(19) United States
(12) Patent Application Publication
(10) Pub. No.: US 2006/0263950 A1
(43) Pub. Date: Nov. 23, 2006

(54) Method of manufacturing semiconductor device

(75) Inventors: Yung-Jun Kim, Suwon-si (KR); Kyung-Hyun Kim, Seoul (KR); Ki-Jong Park, Yongin-si (KR); Hyo-Jin Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/434,176

(22) Filed: May 16, 2006

(30) Foreign Application Priority Data
May 23, 2005 (KR) 2005-42912

(51) Int. Cl. H01L 21/84

(52) U.S. Cl. 438/149

(57) ABSTRACT

In a method of manufacturing a semiconductor device having a stacked structure, an amorphous silicon layer may be formed on a first single crystalline silicon layer. An amorphous state of the amorphous silicon layer may be converted into a single crystalline state to form a preliminary second single crystalline silicon layer having protrusions. The protrusions may be polished to form a second single crystalline silicon layer.

### PRIORITY CLAIM

A claim of priority is made under 35 U.S.C. § 119 to Korean Patent Application No. 2005-42912 filed on May 23, 2005, the disclosure of which is incorporated herein by reference in its entirety.

### BACKGROUND OF THE INVENTION

1. Field of the Invention

Example embodiments of the present invention relate to a method of manufacturing a semiconductor device. More particularly, example embodiments of the present invention relate to a method of manufacturing a semiconductor device having a stacked structure.

2. Description of the Related Art

In general, a solid may be classified as having a single crystalline state, a poly-crystalline state, or an amorphous state. A solid having a single crystalline state has only one crystalline structure; a solid having a poly-crystalline state may have many crystalline structures; a solid having an amorphous state has atoms irregularly arranged therein. Because a solid having a poly-crystalline state may have many crystalline structures, the solid may include grain boundaries. The grain boundaries may reduce or prevent movement of a carrier, for example, an electron or a hole.

A single crystalline silicon layer may be employed as a channel layer (e.g., an active region) in a semiconductor device having a stacked structure or in a system-on-chip (SOC). An example of a semiconductor device having a stacked structure may be a static random access memory (SRAM) device having thin film transistors (TFT).

Methods of manufacturing a single crystalline silicon layer used as a channel layer are conventionally disclosed and known.

### SUMMARY OF THE INVENTION

Example embodiments of the present invention provide a method of manufacturing a semiconductor device, wherein the method may be capable of more efficiently forming a single crystalline silicon layer having better uniformity.

In an example embodiment of the present invention, a method of manufacturing a semiconductor device may include forming an amorphous silicon layer on a first single crystalline silicon layer, converting an amorphous state of the amorphous silicon layer into a single crystalline state to form a preliminary second single crystalline silicon layer having protrusions, and polishing the preliminary second single crystalline silicon layer to form a second single crystalline silicon layer.

In another example embodiment of the present invention, a method of manufacturing a semiconductor device may include forming a first semiconductor structure on a first single crystalline silicon layer, forming a first insulating layer pattern having an opening on the first semiconductor structure and first single crystalline silicon layer, forming a first seed layer including single crystalline silicon in the opening, forming an amorphous silicon layer on the first seed layer and the first insulating layer pattern, converting an amorphous state of the amorphous silicon state into a single crystalline state to form a preliminary second single crystalline silicon layer having protrusions, and polishing the preliminary second single crystalline silicon layer to form a second single crystalline silicon layer.

### BRIEF DESCRIPTION OF THE DRAWINGS

Example embodiments of the present invention will become readily apparent by reference to the following detailed description when considered in conjunction with the accompanying drawings in which:

FIGS. 1 to 8 are cross-sectional views illustrating a method of manufacturing a semiconductor device in accordance with an example embodiment of the present invention;

FIG. 9 illustrates a conventional art laser irradiator;

FIGS. 10 to 20 are cross-sectional views illustrating a method of manufacturing a semiconductor device in accordance with an example embodiment of the present invention; and

FIG. 21 is a cross-sectional view illustrating a semiconductor device manufactured in accordance with an example embodiment of the present invention.

### DESCRIPTION OF EXAMPLE EMBODIMENTS OF THE INVENTION

Example embodiments of the present invention will be described with reference to the accompanying drawings. The example embodiments of the present invention may, however, be embodied in many different forms and should not be construed as limited to the example embodiments set forth herein. Rather, the example embodiments are provided so that disclosure of the present invention will be thorough and complete, and will fully convey the scope of the present invention to those skilled in the art. The features of example embodiments of the present invention may be employed in various and numerous embodiments without departing from the scope of the present invention. In the drawings, the size and relative sizes of layers and regions may be exaggerated for clarity. The drawings are not to scale. Like reference numerals refer to like elements throughout.

It will be understood that when an element or layer is referred to as being “on”, “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Example embodiments of the present invention are described with reference to cross-section illustrations that are schematic illustrations of idealized example embodiments of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature of a device and are not intended to limit the scope of the present invention.

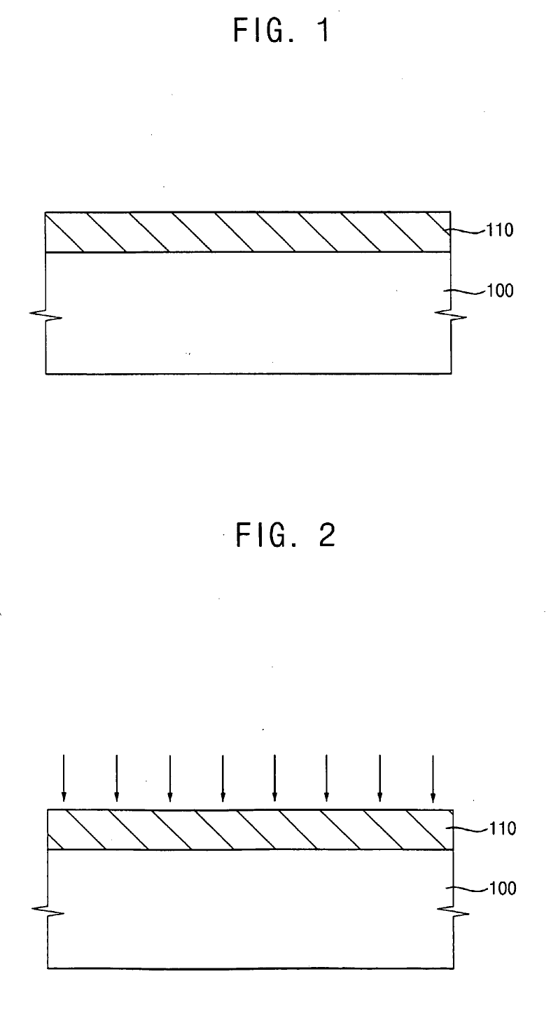

FIGS. 1 to 8 are cross-sectional views illustrating a method of manufacturing a semiconductor device in accordance with an example embodiment of the present invention.

Referring to FIG. 1, an amorphous silicon layer 110 may be formed on a first single crystalline silicon layer 100. The first single crystalline silicon layer 100 may include a single crystalline silicon. The first single crystalline silicon layer 100 may be a silicon substrate formed by a Czochralski (CZ) method or a float-zoning (FZ) method. The first single crystalline silicon layer 100 may be a silicon-on-insulator (SOI) substrate, or a single crystalline silicon layer formed by thermally treating a layer of amorphous silicon. The first single crystalline silicon layer 100 may be formed by thermally treating a layer of amorphous silicon. In example embodiments of the present invention, a selective epitaxial growth (SEG) process may be performed on a single crystalline silicon seed layer to form the first single crystalline silicon layer 100. The SEG process may be a liquid phase epitaxy process, a vapor phase epitaxy process, or a molecular beam epitaxy process.

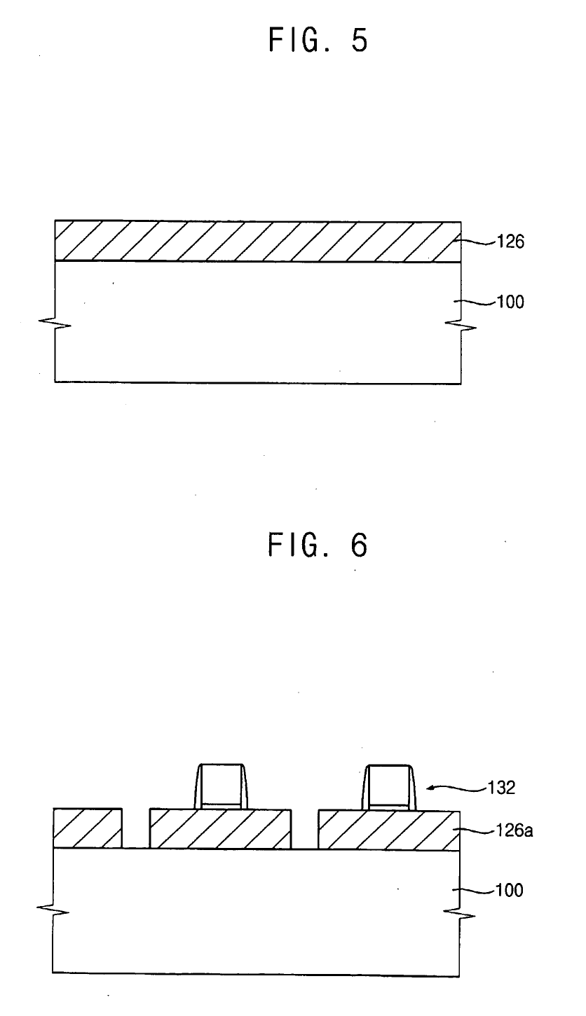

The amorphous silicon layer 110 may be formed by a chemical vapor deposition (CVD) process. However, other well-known processes to form the amorphous silicon layer 110 may be used. The amorphous silicon layer 110 may have a desired thickness which may enable a second single crystalline silicon layer 126 (FIG. 5) subsequently formed by thermally treating the amorphous silicon layer 110 to be efficiently used as a channel layer (e.g., an active region) of a semiconductor, for example, an SRAM device having a stacked structure.

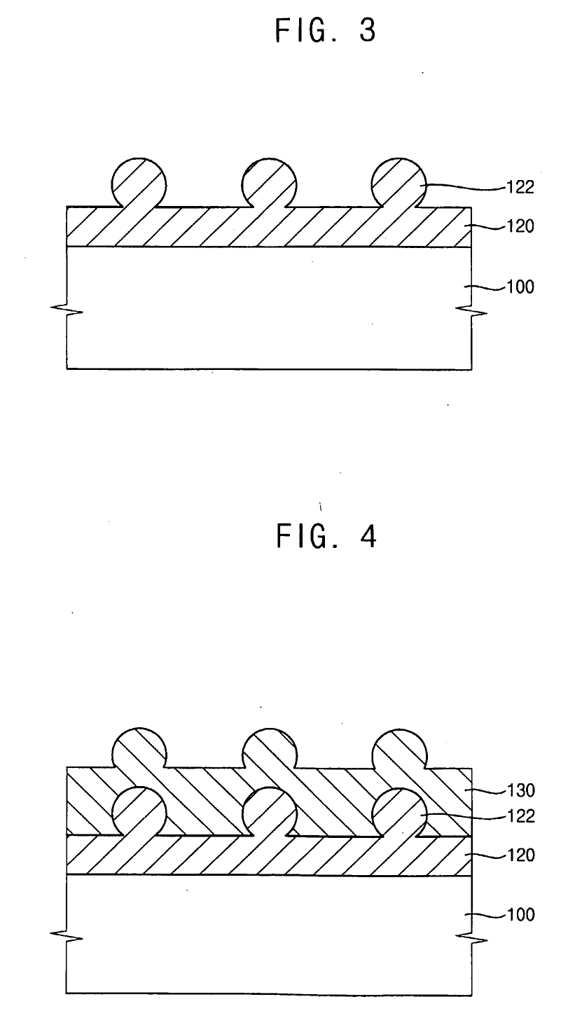

Referring to FIGS. 2 and 3, laser beams may be irradiated onto the amorphous silicon layer 110. A laser irradiator 135 (FIG. 9) capable of scanning the amorphous silicon layer 110 with laser beams may be employed to irradiate the laser beams onto an entire surface of the amorphous silicon layer 110. The laser beams irradiated from the laser irradiator 135 may be excimer lasers. An excimer laser is a type of gas laser. Because the laser irradiator 135 is capable of scanning the amorphous silicon layer 110 with laser beams, a time required to irradiate the laser beams onto the entire surface of the amorphous silicon layer 110 may be shorter. The laser beams irradiated onto the amorphous silicon layer 110 may convert the amorphous silicon layer 110 having an amorphous state into a preliminary second single crystalline silicon layer 120 having a single crystalline state.

The amorphous silicon layer 110 may be melted by the laser beams to convert the amorphous silicon layer 110 into a liquid state. The liquid state may be generated between a surface of the amorphous silicon layer 110 and an interface between the amorphous silicon layer 110 and the first single crystalline silicon layer 100. After a solid state of the amorphous silicon layer 110 is converted into a liquid state, the liquid state of the amorphous silicon layer 110 may be converted into a single crystalline state by using the first single crystalline silicon layer 100 as a seed layer. Thus, the amorphous silicon layer 110 exposed by the laser beams may be converted into the preliminary second single crystalline silicon layer 120 having a single crystalline state. A phase change may only occur in the amorphous silicon layer 110. In other words, the laser beams may have no effect on the first single crystalline silicon layer 100, due to a difference in absorption coefficients between the amorphous silicon layer 110 and the first single crystalline silicon layer 100.

The laser beams may be irradiated until the amorphous silicon layer 110 is completely converted into the preliminary second single crystalline silicon layer 120. A conversion of the amorphous silicon layer 110 into the preliminary second single crystalline silicon layer 120 may proceed in a horizontal direction as well as in a vertical direction. The amorphous state of the amorphous silicon layer 110 may be converted into a single crystalline state in a few nanoseconds. Thus, although the solid state of the amorphous silicon layer 110 may be converted into a liquid state, the amorphous silicon layer 110 does not flow. That is, a shape of the amorphous silicon layer 110 may be maintained even though the solid state of the amorphous silicon layer 110 may be converted into a liquid state.

The laser beams may have energy sufficient to melt a lower portion as well as an upper portion of the amorphous silicon layer 110, because a conversion of an amorphous state into a single crystalline state may proceed from a surface of the amorphous silicon layer 110 to an interface between the amorphous silicon layer 110 and the first single crystalline silicon layer 100. Thus, the energy of the laser beams may be determined based on a thickness of the amorphous silicon layer 110. A melting point of the amorphous silicon layer 110 is about 1,410° C. The energy of the laser beams should be sufficient to heat the amorphous silicon layer 110 to about 1,410° C.

After the irradiation of the laser beams, the first single crystalline silicon layer 100 and the amorphous silicon layer 110 may be thermally treated. During the thermal treatment, a temperature gradient in the amorphous silicon layer 110 may decrease to convert a phase of the amorphous silicon layer 110. Because the temperature gradient is reduced during thermal treatment, generation of grain boundaries may be reduced in the preliminary second single crystalline silicon layer 120. If a thermal treatment occurs at a temperature below about 200° C., grain boundaries may be generated in the second single crystalline silicon layer 120. If a thermal treatment occurs at a temperature of above about 600° C., it may be difficult to prepare a heater device suitable for the thermal treatment. The thermal treatment may be performed at a temperature of about 200° C. to about 600° C. If the thermal treatment is performed at a temperature of about 400° C., the temperature gradient may be sufficiently reduced.

As described above, a time required to convert the amorphous silicon layer 110 into the preliminary second single crystalline silicon layer 120 by using laser beams is about a few nanoseconds. Thus, the preliminary second single crystalline silicon layer 120 may have reduced or no defects. In addition, because the first single crystalline silicon layer 100 may be used as a seed layer, the preliminary second single crystalline silicon layer 120 may have reduced grain boundaries. Furthermore, because the first single crystalline silicon layer 100 may be used as a seed layer, the preliminary second single crystalline silicon layer 120 may have a crystalline structure substantially similar to that of the first single crystalline silicon layer 100. In other words, a Miller index of the preliminary second single crystalline silicon layer 120 may be substantially similar to that of the first single crystalline silicon layer 100.

As shown in FIG. 3, the preliminary second single crystalline silicon layer 120 may include a protrusion 122, which protrudes above the preliminary second single crystalline silicon layer 120. The protrusion 122 may form when the amorphous silicon layer 110 is converted into the preliminary second single crystalline silicon layer 120. One possible explanation as to why the protrusion 122 forms is that silicon atoms in a liquid portion of the amorphous silicon layer 110 are horizontally attracted by a surface tension toward a solid portion of the amorphous silicon layer 110 while the liquid portion of the amorphous silicon layer 110 is solidifying. As the silicon atoms in the liquid portion are attracted toward the solid portion, a thickness of the solid portion may increase. Thus, the protrusion 122 may be formed. That is, the protrusion 122 may be formed by a difference in density between the liquid portion and the solid portion. Thus, the preliminary second single crystalline silicon layer 120 may be divided into a first portion where the protrusion 122 is formed and a second portion where the protrusion 122 is not formed. The first and second portions also may have first and second thicknesses, respectively. The first thickness may be about twice the thickness of the second. Thus, it may be difficult to perform a patterning process (e.g., a photolithography process) on the preliminary second single crystalline silicon layer 120. In addition, if a patterning process is performed on the preliminary second single crystalline silicon layer 120 without first removing the protrusion 122, a portion of the protrusion 122 may remain after the patterning process. Thus, it may be difficult to form subsequent structures on the preliminary second single crystalline silicon layer 120. Accordingly, the protrusion 122 may be removed.

Hereinafter, processes for removing a protrusion 122 on a preliminary second single crystalline silicon layer 120 will be described.

Referring to FIG. 4, a capping layer 130 may be formed on the preliminary second single crystalline silicon layer 120 to cover the protrusion 122. The capping layer 130 may substantially conform to the preliminary second single crystalline silicon layer 120 having the protrusion 122 so that the capping layer 130 may have a convex portion vertically corresponding to the protrusion 122. The capping layer 130 may be formed of an oxide material. However, other well-known materials used to form a capping layer may be used.

The capping layer 130 may be optionally formed to increase the efficiency of a subsequently performed planarization process. Thus, in an example embodiment of the present invention, the planarization process may be performed directly on the preliminary second single crystalline silicon layer 120 without forming the capping layer 130.

Referring to FIG. 5, the capping layer 130 and the protrusion 122 may be polished by a planarization process to remove the capping layer 130 and the protrusion 122, and to form a second single crystalline silicon layer 126. The planarization process may be an etch-back process or a chemical mechanical polishing (CMP) process. These processes may be used alone or in combination. Other well-known planarization process may be used.

In an example embodiment of the present invention, the planarization process may be a CMP process. The CMP process may use a slurry composition including deionized (DI) water and abrasives of metal oxide. Fumed silica may be used as the abrasive in the slurry composition. Furthermore, because the fumed silica may include silicon oxide (SiO₂), which may be used as an insulating material to form an insulating layer, the fumed silica may not serve as a foreign substance even though the fumed silica remains on the insulating layer. A polishing rate of the CMP process may be substantially in proportion to a surface area per weight of the funned silica. That is, the polishing rate of the CMP process may be substantially inversely proportional to a size of the fumed silica. If the surface area per weight of the fumed silica is below about 100 m²/g, the polishing rate may be relatively low. On the other hand, if the surface area per weight of the fumed silica is above about 300 m²/g, it may be difficult to reduce the size of the fumed silica. The surface area per weight of the fumed silica may be about 100 m²/g to about 300 m²/g. For example, the surface area per weight of the fumed silica may be about 130 m²/g to about 300 m²/g.

Referring to FIG. 6, the second single crystalline silicon layer 126 may be partially removed to form a second single crystalline silicon layer pattern 126a A photoresist layer (not shown) may be formed on the second single crystalline silicon layer 126. Exposure and development processes may be performed on the photoresist layer to form a photoresist layer pattern (not shown). An etching process may be performed on the second single crystalline silicon layer 126 by using the photoresist layer pattern as an etch mask. Thus, the second single crystalline silicon layer pattern 126a may be formed. A semiconductor structure 132 (e.g., a metal wire, a logic device, etc.) may be formed on the second single crystalline silicon layer pattern 126a. Because the second single crystalline silicon layer pattern 126a may have a better surface profile, electric characteristics of the semiconductor structure 132 may be improved.

The second single crystalline silicon layer 126 may be used as a channel layer (e.g., an active region) of a semiconductor device (e.g., an SRAM structure) having a stacked structure. Thus, the protrusion 122 may be removed from the preliminary second single crystalline silicon layer 120 to improve uniformity of a channel layer.

As described above, the protrusion 122 may be removed from the preliminary second single crystalline silicon layer 120. However, if the preliminary second single crystalline silicon layer 120 is excessively polished during the removal of the protrusion 122, the second single crystalline silicon layer 126 used as the channel layer may be damaged.

In example embodiments of the present invention, a time required to perform a CMP process may be controlled to partially remove the protrusion 122 to limit damage to the second single crystalline silicon layer 126. Accordingly, a portion of the protrusion 122 may remain on the second single crystalline silicon layer 126.

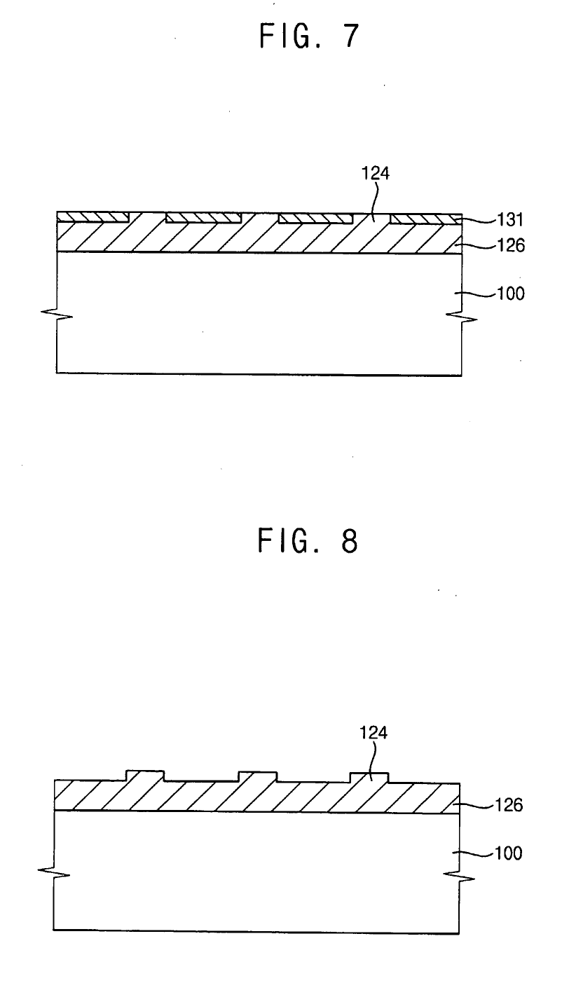

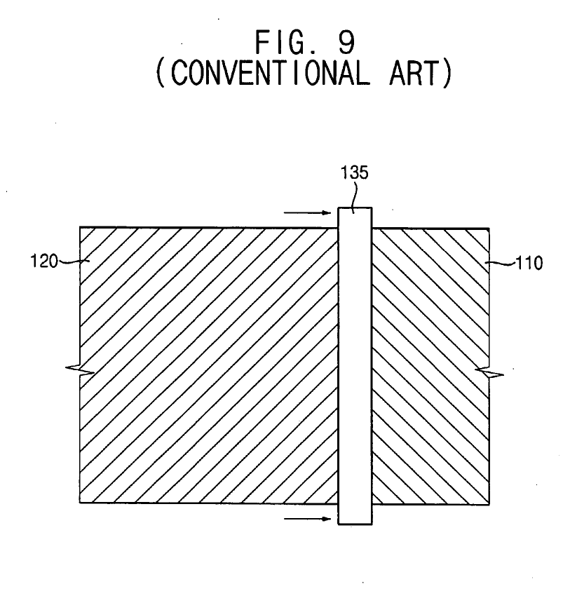

Referring to FIGS. 7 and 8, a CMP process may be performed for a desired time to leave a portion, for example, a residual protrusion 124, on the second single crystalline silicon layer 126. The residual protrusion 124 may have a desired thickness as to not have an influence on uniformity of the second single crystalline silicon layer 126.

As described above, the preliminary second single crystalline silicon layer 120 may include first and second portions having first and second thicknesses, respectively. Because the protrusion 122 may only be included in the first portion, the first thickness may be about twice the thickness of the second thickness. A thickness of the second single crystalline silicon layer 126 may be substantially the same as the second thickness. A thickness of the residual protrusion 124 may be more than about 0.4 times the second thickness. The second crystalline silicon layer 126 on which the residual protrusion 124 is formed may not be efficiently used as the channel layer. Thus, the thickness of the residual protrusion 124 may be no more than about 0.4 times the second thickness.

If the residual protrusion 124 is formed on the second silicon crystalline silicon layer 126 by controlling the CMP process time, a portion of the capping layer 130, for example, a residual capping layer 131, may also remain on the second single crystalline silicon layer 120. Because the residual capping layer 131 may be an insulating layer, the residual capping layer 131 may not be used as the channel layer; and therefore, it may be necessary to remove the residual capping layer 131.

The residual capping layer 131 may be removed by an etching process. The etching process may use an etching solution capable of etching the residual capping layer 131 more rapidly than the second single crystalline silicon layer 126. Negligible amounts of the residual protrusion 124 and the second single crystalline silicon layer 126 may be removed by the etching solution. In other words, the residual capping layer 131 may be selectively removed in the etching process using an etching solution. However, the residual protrusion 124 may still remain on the second single crystalline silicon layer 126 even after the etching process.

In order to etch oxide, a fluorine-based wet etching process or a plasma dry etching process using fluorine-based material, for example, tetrafluoromethane (CF₄) or trifluoromethane (CHF₃), may be employed. For an example, an etching solution used in a fluorine-based wet etching process may include hydrogen fluoride. In another example, an etching solution used in a fluorine-based wet etching process may be a buffer oxide etchant (BOF) solution. In order to etch silicon, a wet etching process using an aqueous solution including hydrofluoric acid, acetic acid, and nitric acid, or a plasma dry etching process may be employed. There may be a difference in an etch rate between oxide and silicon, if an etching process is performed on the oxide and silicon.

If a CMP process is performed directly on the preliminary second single crystalline silicon layer 120 without forming the capping layer 130, the residual capping layer 131 need not be formed. Thus, the etching process performed to remove the residual capping layer 131 need not be required.

As described above, the CMP process may be performed on the protrusion 122 to completely or partially remove the protrusion 122 to form the preliminary second single crystalline silicon layer 120 with better uniformity. If the preliminary second single crystalline silicon layer 120 is used as a channel layer of the semiconductor device (e.g., an SRAM structure) having a stacked structure, higher integration of the semiconductor device may be realized.

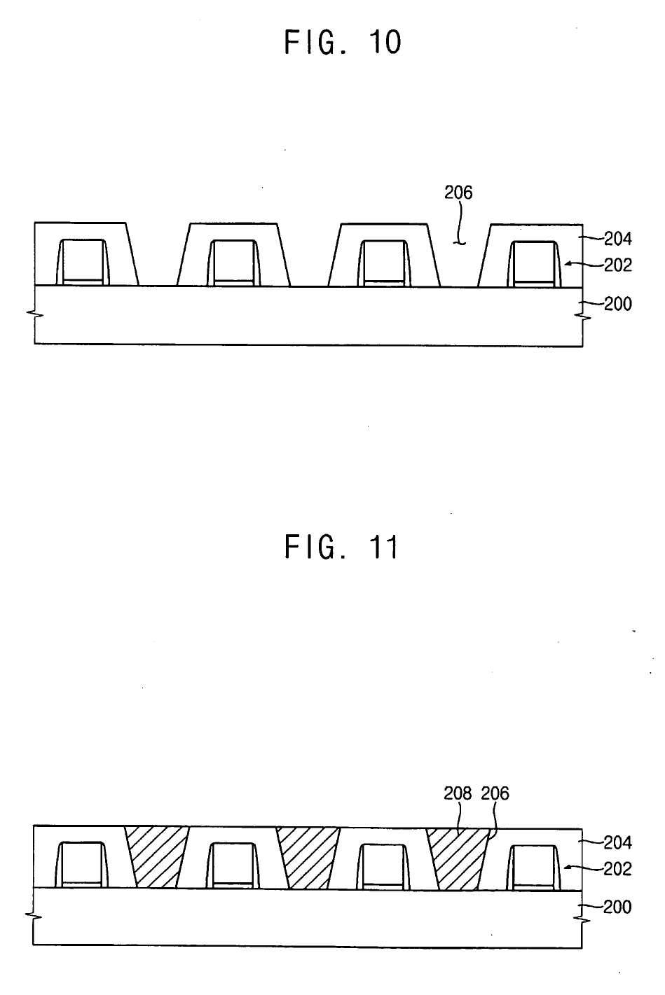

FIGS. 10 to 20 are cross-sectional views illustrating a method of manufacturing a semiconductor device in accordance with an example embodiment of the present invention.

Referring to FIG. 10, a first semiconductor structure 202 including a gate electrode may be formed on a first single crystalline silicon layer 200. The first single crystalline silicon layer 200 may be a silicon substrate or an SOI substrate. The first semiconductor structure 202 may include various other structures (e.g., a metal wire, a logic device, etc.) as well as the gate electrode. In other words, in addition to the gate electrode, various other structures may be formed on the first single crystalline silicon layer 200. An insulating layer (not shown) may be formed on the first single crystalline silicon layer 200 to cover the first semiconductor structure 202. The insulating layer may be formed using oxide. However, other materials well known in the art may be used to form the insulating layer. A photoresist pattern (not shown) may be formed on the insulating layer. The insulating layer may be etched using the photoresist pattern as an etch mask so that an opening 206 partially exposing the first single crystalline silicon layer 200 may be formed through the insulating layer. An insulating layer pattern 204 having the opening 206 may be formed on the first single crystalline silicon layer 200.

Referring to FIG. 11, a seed layer 208 may be formed in the opening 206. The seed layer 208 may be formed by a SEG process. However, other processes well known in the art may be performed to form the seed layer 208. The SEG process may be a vapor phase epitaxy process.

The vapor phase epitaxy process may be performed on a portion of the first single crystalline silicon layer 200, for example, the portion exposed by the opening 206. The seed layer 208 including single crystalline silicon may grow from the portion of the first single crystalline silicon layer 200. The SEG process may be performed until the seed layer 208 fills the opening 206. Thus, the opening 206 may be filled with the seed layer 208. Because the seed layer 208 may be formed by a SEG process, the seed layer 208 may have a crystalline structure substantially similar to that of the first single crystalline silicon layer 200.

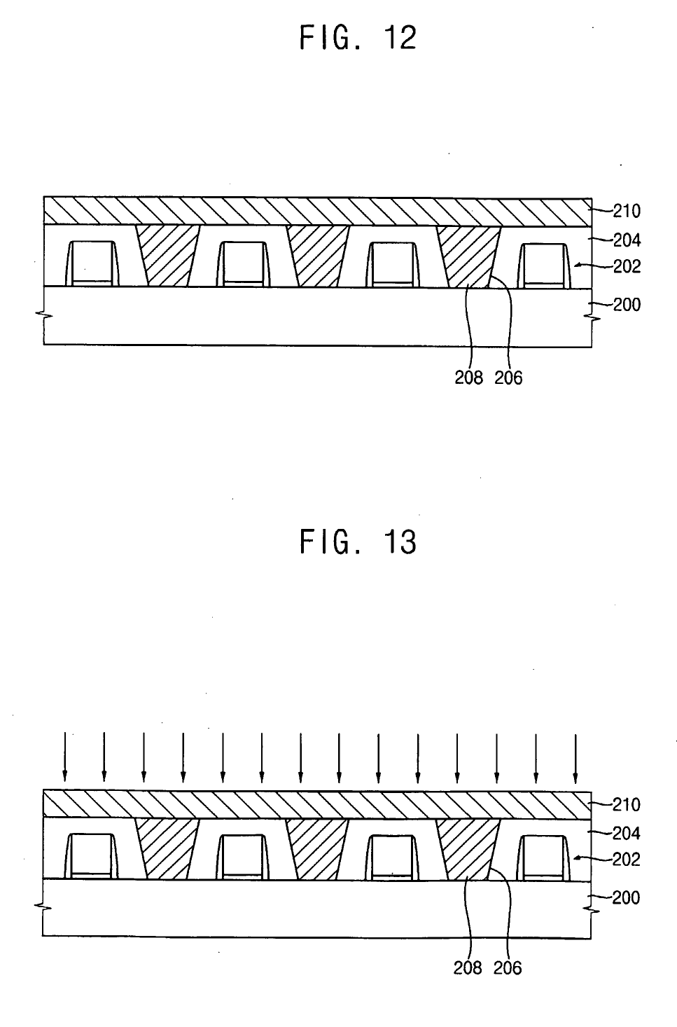

Referring to FIG. 12, an amorphous silicon layer 210 may be continuously formed on the insulating layer pattern 204 and the seed layer 208. The amorphous silicon layer 210 may be formed by a CVD process. However, other processes well known in the art may be performed to form the amorphous silicon layer 210. A thickness of the amorphous silicon layer 210 may be substantially the same as that of an amorphous silicon layer 110 illustrated in FIG. 1. Thus, further detailed explanation thereof will be omitted.

Referring to FIG. 13, laser beams may be irradiated onto the amorphous silicon layer 210. A laser irradiator, which may irradiate the laser beams onto the amorphous silicon layer 210, may be substantially similar to the one illustrated in FIG. 9. Thus, further detailed explanation thereof will be omitted. In addition, processes for converting the amorphous silicon layer 210 into a preliminary second single crystalline silicon layer 220 may be substantially similar to those processes previously explained. Thus, further detailed explanation thereof will be omitted.

A time required to convert the amorphous silicon layer 210 into the preliminary second single crystalline silicon layer 220 may be about a few nanoseconds. Accordingly, the preliminary second single crystalline silicon layer 220 may have reduced or no defects. In addition, because the preliminary second single crystalline silicon layer 220 may grow from the seed layer 208, the preliminary second single crystalline silicon layer 220 may have a Miller index substantially similar to that of the seed layer 208.

The amorphous silicon layer 210 may be efficiently converted into the preliminary second single crystalline silicon layer 220 with little or no grain boundaries with the aid of the seed layer 208 and laser irradiation of the amorphous silicon layer 210. Because the preliminary single crystalline silicon layer 220 has few or no grain boundaries, the preliminary single crystalline silicon layer 220 may have a crystalline structure capable of more efficiently forming a channel.

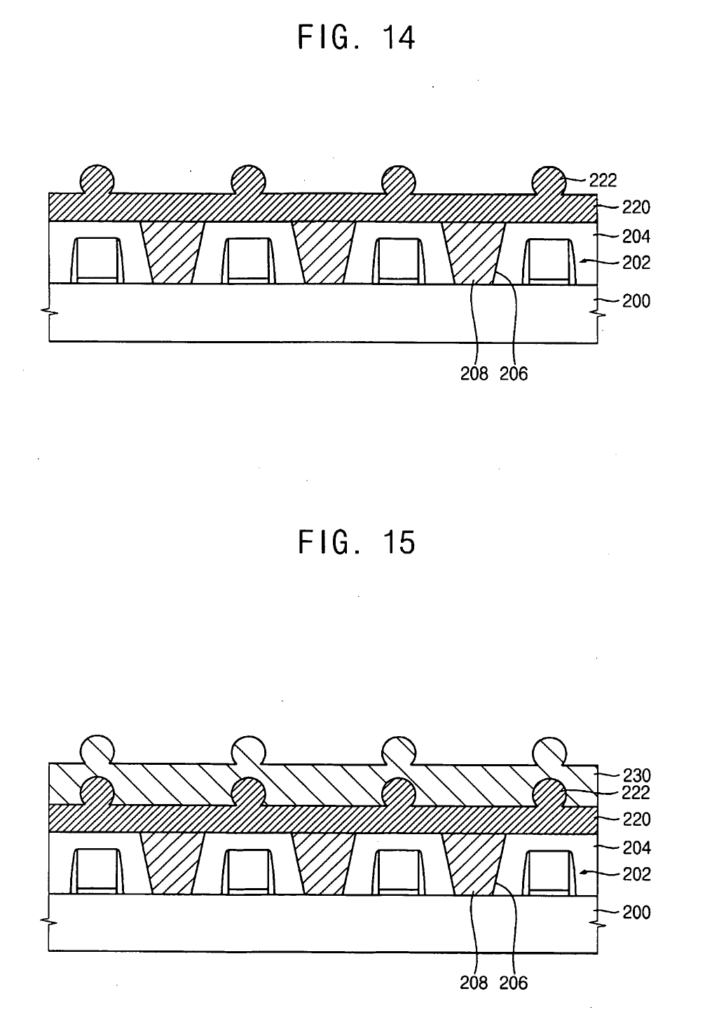

Referring to FIG. 14, the preliminary second single crystalline silicon layer 220 may include a protrusion 222. The protrusion 222 may be formed during the conversion of the amorphous silicon layer 210 into the preliminary second single crystalline silicon layer 220. The protrusion 222 may be substantially the same as the protrusion 122 illustrated in FIG. 3. Thus, further detailed explanation thereof will be omitted.

Referring to FIG. 15, a capping layer 230 may be formed on the preliminary second single crystalline silicon layer 220 including the protrusion 222. The capping layer 230 may be formed in a substantially similar manner as the capping layer illustrated in FIG. 4. Thus, further detailed explanation thereof will be omitted.

The capping layer 230 may be optionally formed to increase efficiency of a planarization process, which may be subsequently performed. In an example embodiment of the present invention, the planarization process may be performed directly on the preliminary second single crystalline silicon layer 220 without forming the capping layer 230.

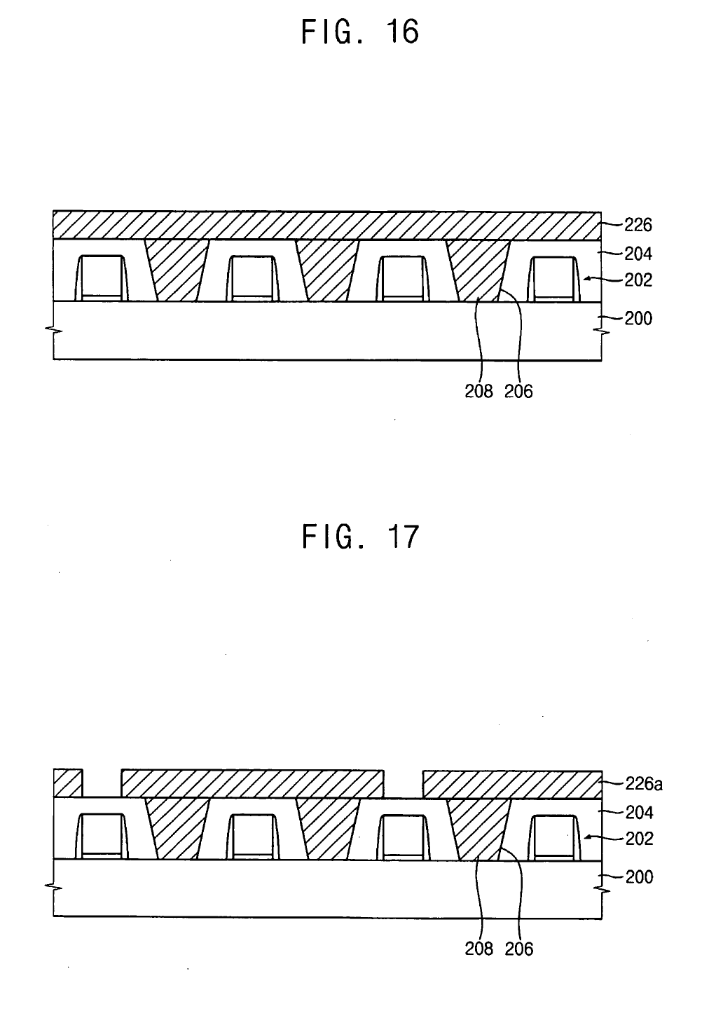

Referring to FIG. 16, the capping layer 230 and the protrusion 222 may be polished until they are completely removed. A second single crystalline silicon layer 226 may be formed on the seed layer 208 and the insulating layer pattern 204. Processes to completely remove the capping layer 230 and the protrusion 222 may be substantially similar to those processes previously explained with respect to FIG. 5. Thus, further detailed explanation thereof will be omitted.

Referring to FIG. 17, the second single crystalline silicon layer 226 may be partially removed so that a second single crystalline silicon layer pattern 226a may be formed. The second single crystalline silicon layer pattern 226a may be formed by processes substantially similar to the process of forming a second single crystalline silicon layer pattern with respect to FIG. 6. Thus, further detailed explanation thereof will be omitted.

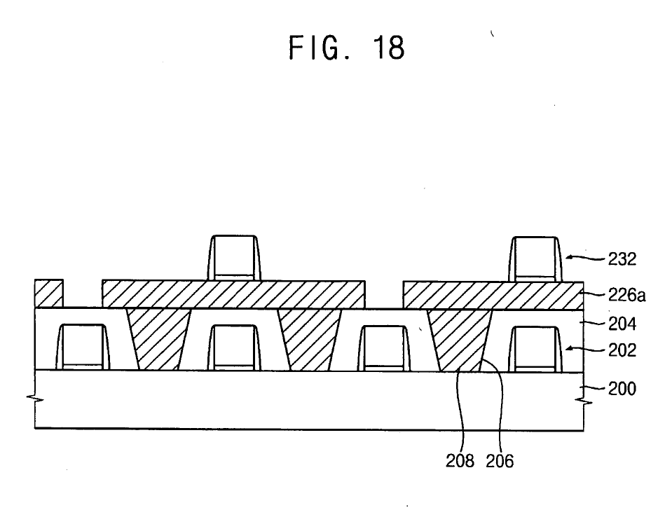

Referring to FIG. 18, the second single crystalline silicon layer pattern 226a may be used as a channel layer (e.g., an active region). A second semiconductor structure 232 including a gate electrode may be formed on the second single crystalline silicon layer pattern 226a. In addition, impurities may be doped into an upper portion of the second single crystalline silicon layer pattern 226a so that source/drain regions may be formed. A channel may be formed between the source/drain regions. The second semiconductor structure 232 formed on the second single crystalline silicon layer pattern 226a may include various structures (e.g., a metal wire, a logic device, etc.) as well as the gate electrode. In order words, the other structures as well as the gate electrode may be formed on the second single crystalline silicon layer pattern 226a.

As described above, a second single crystalline silicon layer 226 may be used as a channel layer. When a protrusion 222 is completely removed from the preliminary second single crystalline silicon layer 226, uniformity of the second single crystalline silicon layer 226 used as a channel layer may be improved.

However, when a preliminary second single crystalline silicon layer 220 is excessively polished to remove a protrusion 222 completely, a second single crystalline silicon layer 226 used as the channel layer may be damaged. Therefore, in an example embodiment of the present invention, a time required to perform a CMP process may be controlled to remove the protrusion 222 partially so that damage to the second single crystalline silicon layer 226 may be limited or prevented. Thus, a portion of the protrusion 222 may remain on the second single crystalline silicon layer 226. The remaining portion may be referred to as a residual protrusion 224. When the residual protrusion 224 remains on the second single crystalline silicon layer 226, a portion of the capping layer 230 may also remain on the second silicon crystalline silicon layer 226. The portion remaining on the capping layer 230 may be referred to as a residual capping layer 231.

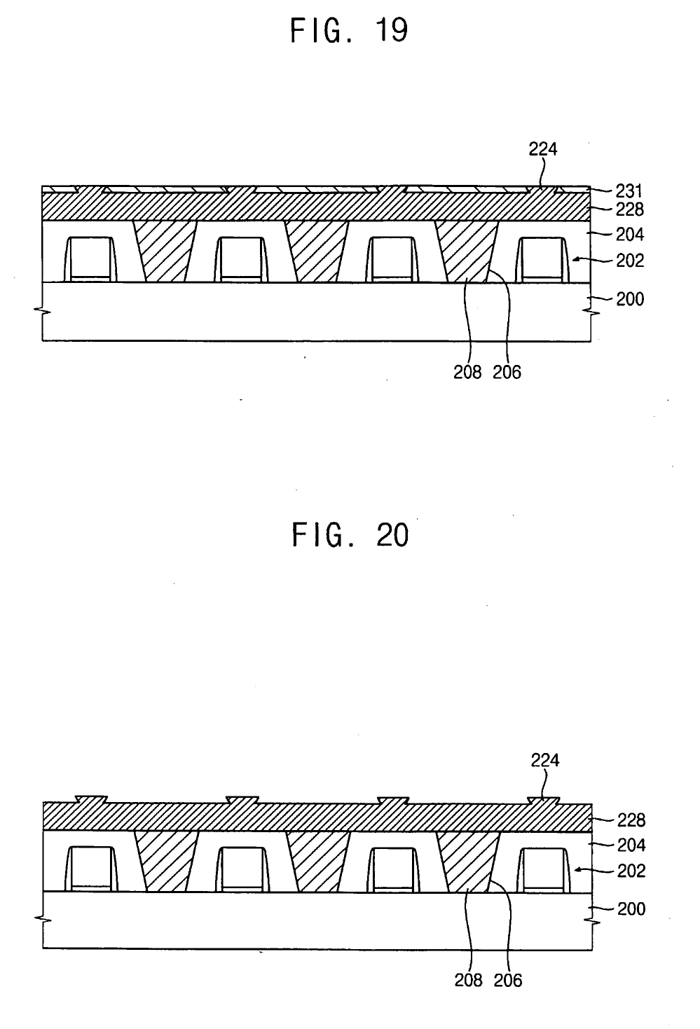

Referring to FIG. 19, a CMP process may be performed for a desired time so that the residual protrusion 224 and the residual capping layer 231 may remain on the second single crystalline silicon layer 226. A process to form and a thickness of the residual protrusion 224 may be substantially similar to that of the residual protrusion 124 illustrated in FIG. 7. Thus, further detailed explanation thereof will be omitted.

Referring to FIG. 20, the capping layer 230 may be an insulating layer, therefore, it may be necessary to remove the residual capping layer 231. The residual capping layer 231 may be removed by an etching process. The etching process employed to remove the residual capping layer 231 may be similar to that employed to remove a residual capping layer illustrated with respect to FIG. 8. Thus, further detailed explanation thereof will be omitted.

In an example embodiment of the present invention, the capping layer 230 need not be formed. When a CMP process is performed without forming the capping layer 230, the residual capping layer 231 may not remain on the second single crystalline silicon layer 220. Thus, it may not be necessary to remove the residual capping layer 231.

As described above, a protrusion may be polished to decrease a height of the protrusion. Thus, a second single crystalline silicon layer having better uniformity may be formed. Because a second single crystalline silicon layer may have better uniformity, the second single crystalline silicon layer may be more efficiently used as a channel layer.

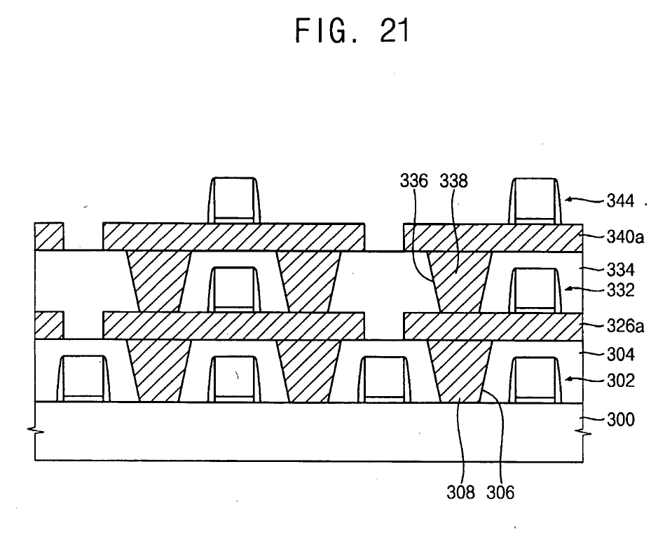

FIG. 21 is a cross-sectional view illustrating a semiconductor device manufactured in accordance with an example embodiment of the present invention.

Referring to FIG. 21, a first semiconductor structure 302, a first insulating layer pattern 304 having a first opening 306, a first seed layer 308, a second single crystalline silicon layer pattern 326a, and a second semiconductor structure 332 may be formed on a first single crystalline silicon layer 300. Processes to form the first semiconductor structure 302, the first insulating layer pattern 304, the first seed layer 308, the second single crystalline silicon layer pattern 326a, and the second semiconductor structure 332 may be substantially similar to the processes illustrated with respect to FIGS. 10 to 21. Thus, further detailed explanation thereof will be omitted.

A second insulating layer pattern 334 having a second opening 336 may be formed on the second single crystalline silicon layer pattern 326a to cover the second semiconductor structure 332. Processes to form the second insulating layer pattern 334 may be substantially similar to the processes of forming the first insulating layer pattern. Thus, further detailed explanation thereof will be omitted.

A second seed layer 338 and a third single crystalline silicon layer pattern 340a may be formed. The second seed layer 338 may be formed in the second opening 336. The third single crystalline silicon layer pattern 340a may be formed on the second insulating layer pattern 334 and the second seed layer 338. Processes for forming the second seed layer 338 and the third single crystalline silicon layer pattern 340 are substantially similar to the processes of forming the first seed layer 308 and the second single crystalline silicon layer pattern 326a. Thus, further detailed explanation thereof will be omitted.

A third semiconductor structure 344 including a gate electrode may be formed on the third single crystalline silicon layer pattern 340a that is used as a channel layer. In addition, source/drain regions may be formed in an upper portion of the third single crystalline silicon layer pattern 340a. A channel may be formed between the source/drain regions. The third semiconductor structure 344 may include other structures (e.g., a metal wire, a logic device, etc.) as well as the gate electrode. In other words, the other structures in addition to the gate electrode may be formed on the third single crystalline silicon layer pattern 340a.

In another example embodiment of the present invention, after the third semiconductor structure 344 is formed on the third single crystalline silicon layer pattern 340a, an n^{th} (“n” is a natural number no less than 3) insulating layer pattern, a p^{th} (“p” is a natural number no less than 3) seed layer, and an r^{th} (“r” is a natural number no less than 4) single crystalline silicon layer may be formed on the third single crystalline silicon layer 340a. The n^{th} insulating layer pattern, the p^{th} seed layer, and the r^{th} single crystalline silicon layer may be substantially formed in a similar manner as the second insulating layer pattern 334, the second seed layer 338, and the third single crystalline silicon layer pattern 340a, respectively.

As described above, the first to r^{th} single crystalline silicon layers may have increased electric characteristics. Thus, when the first to r^{th} single crystalline silicon layers are employed as channel layers, a more highly integrated semiconductor device (e.g., an SRAM device) having a stacked structure may be realized.

According to example embodiments of the present invention, a protrusion formed while an amorphous silicon layer is converted into a single crystalline silicon layer may be polished. Thus, the single crystalline silicon layer may have few or no grain boundaries. In addition, the single crystalline silicon layer may have improved uniformity. As a result, the single crystalline silicon layer may be more efficiently used as a channel layer of a semiconductor device having a stacked structure.

The foregoing is illustrative of example embodiments of the present invention and is not to be construed as limiting thereof. Although example embodiments of this invention have been described, those skilled in the art will readily appreciate that many modifications are possible in example embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the example embodiments disclosed, and that modifications to the disclosed embodiments, as well as other example embodiments, are intended to be included within the scope of the appended claims. The invention is defined by the following claims, with equivalents of the claims to be included therein.

What is claimed is:

1. A method of manufacturing a semiconductor device, the method comprising:
forming an amorphous silicon layer on a first single crystalline silicon layer;
converting an amorphous state of the amorphous silicon layer into a single crystalline state to form a preliminary second single crystalline silicon layer having protrusions; and
polishing the preliminary second single crystalline silicon layer to form a second single crystalline silicon layer.

2. The method of claim 1, wherein the first single crystalline silicon layer is one selected from the group consisting of a silicon substrate formed by a Czochralski method or a float-zoning method, a silicon-on-insulator substrate, and a single crystalline silicon layer formed by thermally treating a layer of amorphous silicon.

3. The method of claim 1, wherein converting the amorphous state of the amorphous silicon layer into the single crystalline state includes:
irradiating laser beams onto the amorphous silicon layer to melt a first portion of the amorphous silicon layer; and
solidifying the first portion of the amorphous silicon layer by using the first single crystalline silicon layer as a seed.

4. The method of claim 1, wherein polishing the preliminary second single crystalline silicon layer having the protrusions includes:
forming a capping layer on the preliminary second single crystalline silicon layer; and
polishing the capping layer to remove the protrusions.

5. The method of claim 4, wherein the capping layer is polished by a chemical mechanical polishing process.

6. The method of claim 1, wherein polishing the preliminary second single crystalline silicon layer includes:
forming a capping layer on the preliminary second single crystalline silicon layer; and
partially removing the capping layer to form a residual capping layer, the residual capping layer being thinner than the capping layer; and
removing the residual capping layer.

7. The method of claim 6, wherein the capping layer is partially removed by a chemical mechanical polishing process.

8. The method of claim 6, wherein the residual capping layer is removed using an etching solution capable of etching the capping layer more rapidly than the preliminary second single crystalline silicon layer.

9. A method of manufacturing a semiconductor device, the method comprising:
forming a first semiconductor structure on a first single crystalline silicon layer;
forming a first insulating layer pattern having an opening on the first semiconductor structure and first single crystalline silicon layer;
forming a first seed layer including the single crystalline silicon in the opening;
forming an amorphous silicon layer on the first seed layer and the first insulating layer pattern;
converting an amorphous state of the amorphous silicon layer into a single crystalline state to form a preliminary second single crystalline silicon layer having protrusions; and
polishing the preliminary second single crystalline silicon layer to form a second single crystalline silicon layer.

10. The method of claim 9, wherein the first seed layer is formed by a selective epitaxial growth process.

11. The method of claim 9, wherein polishing the preliminary second single crystalline silicon layer comprises:
forming a capping layer on the preliminary second single crystalline silicon layer; and
polishing the capping layer to remove the protrusions.

12. The method of claim 11, wherein the capping layer is polished by a chemical mechanical polishing process.

13. The method of claim 9, wherein polishing the preliminary second single crystalline silicon layer includes:
forming a capping layer on the preliminary second single crystalline silicon layer; and
partially removing the capping layer to form a residual capping layer, the residual capping layer being thinner than the capping layer; and
removing the residual capping layer.

14. The method of claim 13, wherein the capping layer is partially removed by a chemical mechanical polishing process.

15. The method of claim 13, wherein the residual capping layer is removed using an etching solution capable of etching the capping layer more rapidly than the preliminary single crystalline silicon layer.

16. The method of claim 9, wherein the first single crystalline silicon layer is one selected from the group consisting of a silicon substrate formed by a Czochralski method or a float-zoning method, a silicon-on-insulator substrate, and a single crystalline silicon layer formed by thermally treating a layer of amorphous silicon.

17. The method of claim 9, wherein converting the amorphous state of the amorphous silicon layer into the single crystalline state includes:
irradiating laser beams onto the amorphous silicon layer to melt a first portion of the amorphous silicon layer; and
solidifying the first portion of the amorphous silicon layer.

18. The method of claim 9, further including:
partially removing the second single crystalline silicon layer; and
forming a second semiconductor structure on the second single crystalline silicon layer.

19. The method of claim 18, further including:
forming a second insulating layer having an opening on the second semiconductor structure and the second single crystalline silicon layer;
forming a second seed layer including single crystalline silicon in the opening;
forming a third single crystalline structure having an opening on the second seed layer and the second insulating layer; and
forming a third semiconductor structure on the third single crystalline structure.

20. The method of claim 19, wherein the first, second, third semiconductor structures include one of a gate, a metal wire, and a logic device.
